(19) United States
(12) Patent Application Publication
(10) Pub. No.: US 2004/0247431 A1
(43) Pub. Date: Dec. 9, 2004

(54) Fan holder with actuator

(76) Inventors: Yun Lung Chen, Tu-chen (TW); Quan Guang Du, Shenzhen (CN)

Correspondence Address: WEI TE CHUNG, FOXCONN INTERNATIONAL, INC., 1650 MEMOREX DRIVE, SANTA CLARA, CA, 95050, US

(21) Appl. No.: 10/863,417

(22) Filed: Jun. 7, 2004

(30) Foreign Application Priority Data
Jun. 6, 2003 (TW) 92210423

(51) Int. Cl. H05K 7/16; F03B 1/00; F04D 23/00; F04D 17/00; F01D 1/00; F04D 1/00; F04D 29/42; F03D 1/00; F03D 3/00; F03B 3/00; F03D 5/00; F03D 11/00; F01D 25/24; F01D 9/00; F03B 11/02

(52) U.S. Cl. 415/182.1

(57) ABSTRACT

A holder (20) is for securing a fan (30) to a panel (41) of a computer enclosure. The holder includes a base (21) having a plurality of resilient posts (29) formed thereon, and a plurality of walls adjoining the base. A cavity is defined between the base and the walls, for accommodating the fan therein. The plurality of walls comprises a top wall (24), a bottom wall (23), and a pair of side walls (22). A pair of latches (25) separately depends from edge portions of the top wall and the bottom wall. An actuator (27) extends over the top wall from edge portions of the side walls. The actuator extends a pair of blocks (28) from a front portion thereof. The panel defines a plurality of cutouts (44, 47) therein for engagingly receiving the latches and blocks of the holder.

### BACKGROUND OF THE INVENTION

1. Field of the Invention

The present invention relates to holders, and particularly to a holder with an actuator which can readily and firmly secure a fan to a panel of a computer enclosure.

2. Related Art

A typical contemporary personal computer comprises a central processing unit (CPU) and a power supply. Heat is generated by the CPU, and resulting heated air is removed away from the CPU by a fan driven by the power supply.

However, a single fan does not always effectively dissipate large amounts of heated air generated from modern powerful CPUs. Accordingly, a second fan is often installed at an outside panel of a computer enclosure, to bring cooling air into the enclosure. The second fan is generally attached to the enclosure with screws. This conventionally requires a tool. The attachment procedure is unduly tedious and inconvenient, especially when the enclosure is small. Furthermore, other components in the enclosure are prone to be accidentally damaged during the attachment procedure.

Another conventional means of attachment of a fan to a computer enclosure is shown in Taiwan Patent Application No. 88217278. A fan holder comprises four lateral spring hooks and two longitudinal spring hooks. The enclosure defines four lateral and two longitudinal slots therein. The hooks respectively extend through the slots of the enclosure and engage therein. Thus, the fan is fastened to the enclosure. The fan holder does not require screws. However, the fan holder is not easily removable from the enclosure when maintenance or replacement is required.

Thus, an improved fan holder which solves the above-mentioned problems is strongly desired.

### SUMMARY OF THE INVENTION

Accordingly, an object of the present invention is to provide a holder with actuator which readily and firmly secures a fan to a panel of a computer enclosure.

Another object of the present invention is to provide a holder with actuator which allows easy removal of a fan from a panel of a computer enclosure.

To achieve the above-mentioned objects, a holder in accordance with the present invention is for securing a fan to a panel of a computer enclosure. The holder includes a base having a plurality of resilient posts formed thereon, and a plurality of walls adjoining the base. A cavity is defined between the base and the walls, for accommodating the fan therein. The plurality of walls comprises a top wall, a bottom wall, and a pair of side walls. A pair of latches separately depends from edge portions of the top wall and the bottom wall. An actuator extends over the top wall from edge portions of the side walls. The actuator extends a pair of blocks from a front portion thereof. The panel defines a plurality of cutouts therein for engagingly receiving the latches and blocks of the holder.

Other objects, advantages and novel features of the present invention will be drawn from the following detailed description of a preferred embodiment of the present invention with attached drawings, in which:

### BRIEF DESCRIPTION OF THE DRAWINGS

FIG. 1 is an exploded, isometric view of a fan holder of the present invention, a panel of a computer enclosure, and a fan;

FIG. 2 is an enlarged, isometric view of the fan holder of FIG. 1, but viewed from another aspect;

FIG. 3 is substantially an assembled view of FIG. 1; and

FIG. 4 is similar to FIG. 3, but viewed from another aspect.

### DESCRIPTION OF THE PREFERRED EMBODIMENT

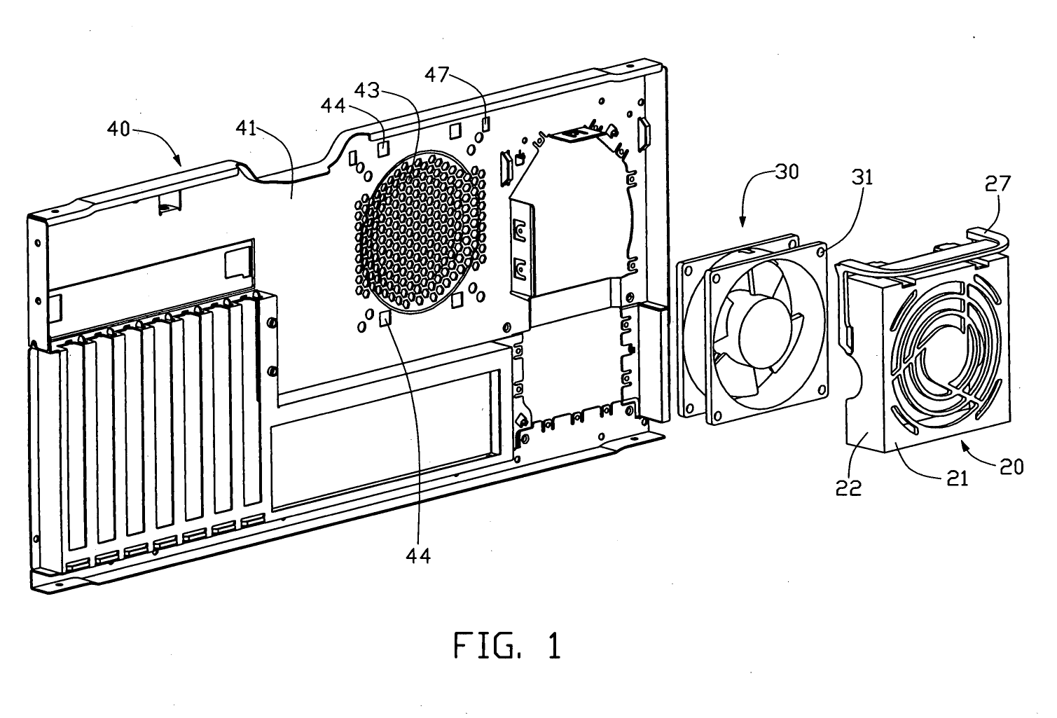

Referring to FIG. 1, a holder 20 of the present invention is used to secure a fan 30 to a panel 41 of a computer enclosure 40.

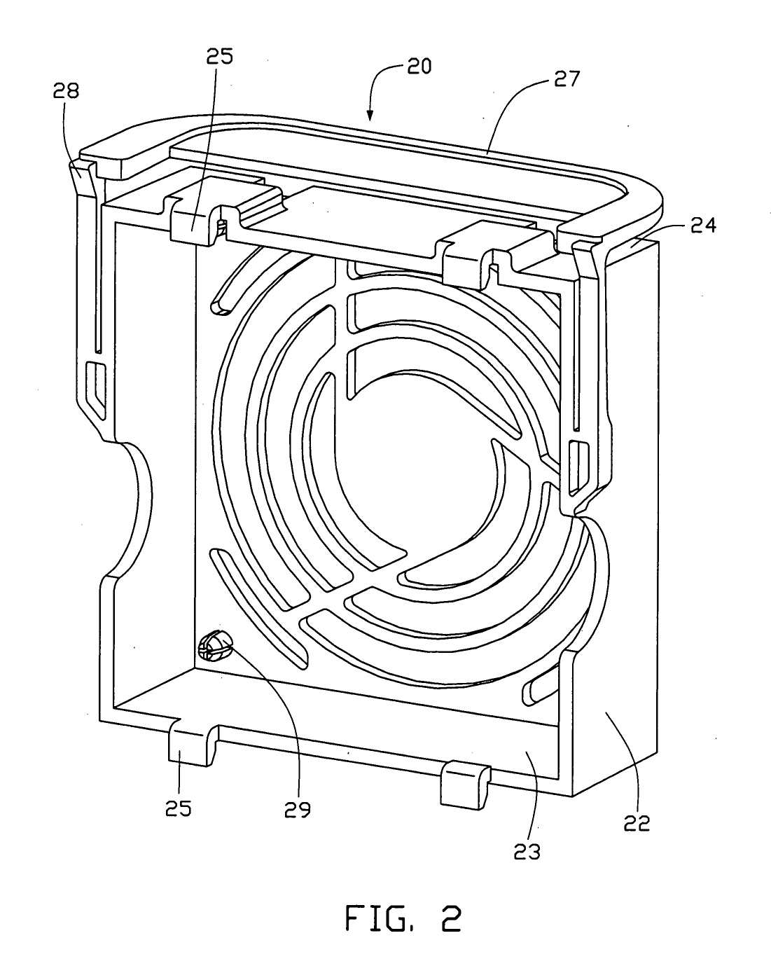

Referring also to FIG. 2, the holder 20 comprises a rectangular base 21, a pair of side walls 22, a top wall 24, and a bottom wall 23. The top wall 24, bottom wall 23 and side walls 22 extend from respective edges of the base 21. The side walls 22 respectively interconnect the top wall 24 and the bottom wall 23. The side, bottom and top walls 22, 23, 24 and the base 21 cooperatively define a cavity (not labeled) therebetween, for receiving the fan 30 therein. A pair of spaced latches 25 depends from an edge of the top wall 24, and another pair of spaced latches 25 depends from an edge of the bottom wall 23. The base 21 defines a vent (not labeled) therein for allowing air flow therethrough. Four elastic posts 29 inwardly extend from four corners of the base 21 respectively. Each post 29 defines a cross-slot therethrough, thereby providing the post 29 with resilient deformability. A generally C-shaped actuator 27 extends upwardly from opposite edge portions of the side walls 22 so that it is suspended over the top wall 24. A pair of blocks 28 extends from opposite ends of the actuator 27 respectively.

The panel 41 defines a vent area 43 therein. Two pairs of spaced first cutouts 44 are defined in the panel 41 above and below the vent area 43 respectively, corresponding to the latches 25 of the holder 20. A pair of spaced second cutouts 47 is defined in the panel 41 above the vent area 43, corresponding to the blocks 28 of the actuator 27.

The fan 30 defines four through holes 31 in four corners thereof respectively, for engagingly receiving the posts 29 of the holder 20.

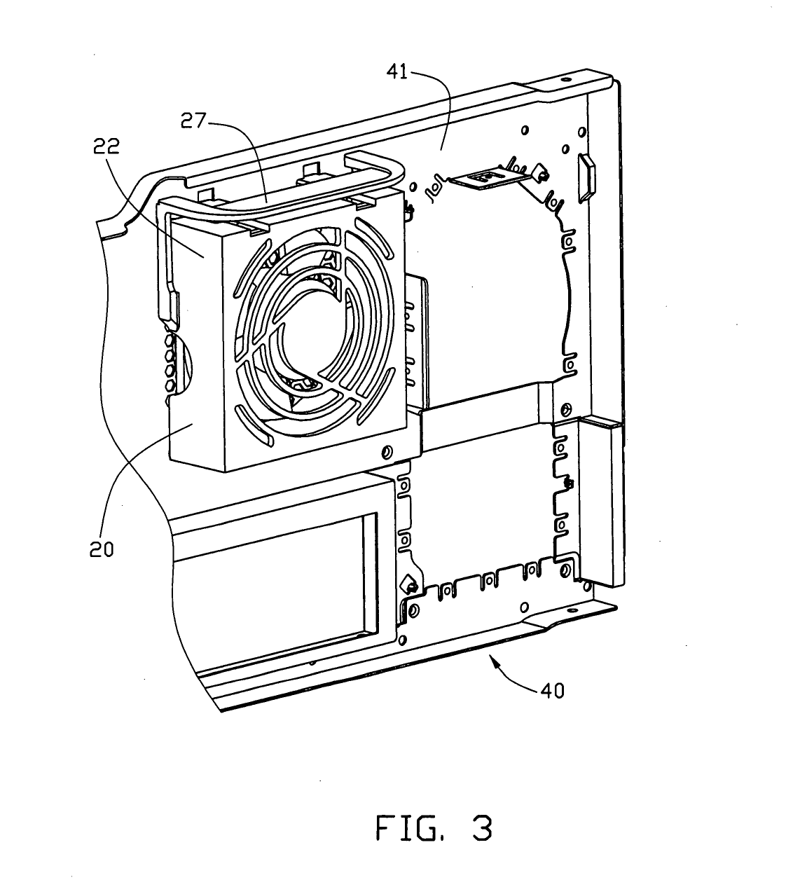

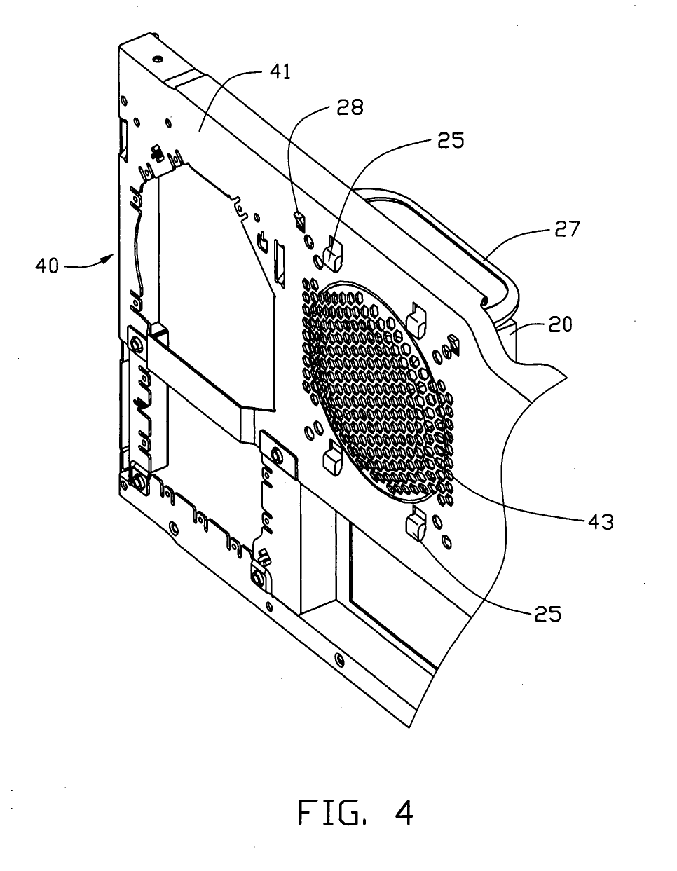

Referring also to FIGS. 3 and 4, in assembly, the fan 30 is received in the cavity of the holder 20. The posts 29 are elastically squeezed and firmly retained in the through holes 31 of the fan 30. The fan 30 is thus securely attached to the holder 20. The combined holder 20 and fan 30 is then placed on the panel 41. The latches 25 of the holder 20 are engagingly received in the first cutouts 44 of the panel 41. Simultaneously, the blocks 28 of the actuator 27 are elastically depressed and snappingly engaged in the second cutouts 47. The combined holder 20 and fan 30 is thus securely attached to the panel 41.

The latches 25 depend from the edge portions of the top wall 24 and the bottom wall 23, and the blocks 28 also extend from the edge portions of the opposite ends of the actuator 27. When the combined bracket 20 and fan 30 is attached to the panel 41, free edges of the top wall 24, bottom wall 23 and side walls 22 of the bracket 20 closely abut a surface of the panel 41. Accordingly, air flow through the bracket 20 is fully utilized for heat dissipation.

In disassembly, the actuator 27 is pressed downwardly, so that the blocks 28 exit the second cutouts 47 of the panel 41. The holder 20 is pulled upwardly, so that the latches 25 are disengaged from the first cutouts 44 of the panel 41. The combined holder 20 and fan 30 is thus easily removed from the panel 41.

It is to be understood, however, that even though numerous characteristics and advantages of the present invention have been set forth in the foregoing description, together with details of the structure and function of the invention, the disclosure is illustrative only, and changes may be made in detail, especially in matters of shape, size, and arrangement of parts within the principles of the invention to full extent indicated by the broad general meaning of the terms in which the appended claims are expressed.

1. A holder for securing a fan to a panel of a computer enclosure, the holder comprising:
a base;
a plurality of walls extending from the base and cooperatively defining a cavity therebetween for accommodating the fan therein, the walls comprising at least one pair of latches for engaging with the panel; and
an actuator having at least one block extending from a front portion thereof for retaining the holder to the panel.

2. The holder as described in claim 1, wherein the base defines a vent area for facilitating air flow.

3. The holder as described in claim 1, wherein the plurality of walls comprises a pair of side walls, and a top wall and a bottom wall connecting between the side walls.

4. The holder as described in claim 1, wherein a pair of latches extends from each of the top wall and the bottom wall.

5. The holder as described in claim 1, wherein the base comprises four posts inwardly extending from four corners thereof respectively, for engaging in the fan.

6. The holder as described in claim 5, wherein each of the posts defines a crossed slot therein.

7. A fan holder assembly comprising:
a fan defining a plurality of holes therein;
a fan holder comprising:
a base; and
a plurality of walls adjoining the base and cooperatively defining a cavity therebetween for accommodating the fan therein, the walls comprising a plurality of latches extending therefrom and an actuator having securing means on a front portion thereof; and
a panel defining a plurality of cutouts engagingly receiving the latches and securing means of the holder, whereby the holder is secured to the panel and the fan is firmly sandwiched between the panel and the holder;
wherein when the actuator is pressed toward the base, the securing means is released from corresponding cutouts and the latches are detachable from corresponding cutouts.

8. The fan holder assembly as described in claim 7, wherein the base defines a vent area for facilitating air flow.

9. The fan holder assembly as described in claim 7, wherein the plurality of walls comprises a pair of side walls, and a top wall and a bottom wall connecting between the side walls.

10. The fan holder assembly as described in claim 9, wherein a pair of latches extends from each of the top wall and the bottom wall.

11. The fan holder assembly as described in claim 7, wherein the base comprises a plurality of posts formed at corners thereof, for engaging in the through holes of the fan.

12. The fan holder assembly as described in claim 11, wherein each of the posts defines a crossed slot therein.

13. The fan holder assembly as described in claim 7, wherein the actuator extends upwardly over the top wall from side edge portions of the side walls.

14. The fan holder assembly as described in claim 13, wherein the securing means comprises a pair of blocks extruding from the front portion of the actuator.
